(19) United States
(12) Patent Application Publication
(10) Pub. No.: US 2024/0113034 A1
(43) Pub. Date: Apr. 4, 2024

(54) METHODS FOR FORMING SEMICONDUCTOR PACKAGE

(71) Applicant: Taiwan Semiconductor Manufacturing Company, Ltd., Hsinchu (TW)

(72) Inventors: Yu-Hung LIN, Taichung City (TW); Wei-Ming WANG, Taichung City (TW); Chih-Hao YU, Tainan City (TW); PaoTai HUANG, Hsinchu County (TW); Pei-Hsuan LO, Hsinchu County (TW); Shih-Peng TAI, Xinpu Township (TW)

(21) Appl. No.: 18/166,109

(22) Filed: Feb. 8, 2023

Related U.S. Application Data
(60) Provisional application No. 63/378,089, filed on Oct. 3, 2022.

(51) Int. Cl. H01L 23/544; H01L 21/768; H01L 23/00; H01L 23/48; H01L 25/00

(52) U.S. Cl. CPC H01L 23/544; H01L 21/76898; H01L 23/481; H01L 24/05; H01L 25/50; H01L 2223/54426; H01L 2224/0401; H01L 2224/05025

(57) ABSTRACT

A method for forming a semiconductor package is provided. The method includes forming a first alignment mark in a first substrate of a first wafer and forming a first bonding structure over the first substrate. The method also includes forming a second bonding structure over a second substrate of a second wafer and trimming the second substrate, so that a first width of the first substrate is greater than a second width of the second substrate. The method further includes attaching the second wafer to the first wafer via the first bonding structure and the second bonding structure, thinning the second wafer until a through-substrate via in the second substrate is exposed, and performing a photolithography process on the second wafer using the first alignment mark.

### CROSS-REFERENCE TO RELATED APPLICATIONS

This application claims the benefit of U.S. Provisional Application No. 63/378,089, filed Oct. 3, 2022, the entirety of which is incorporated by reference herein.

### BACKGROUND

The semiconductor industry continues to improve the integration density of various electronic components (e.g., transistors, diodes, resistors, capacitors, etc.) by continual reductions in minimum feature size, which allow more components to be integrated into a given area. The individual dies are typically packaged separately. A package not only provides protection for semiconductor devices from environmental contaminants, but also provides a connection interface for the semiconductor devices packaged therein.

Three dimensional integrated circuits (3DICs) are a recent development in semiconductor packaging in which multiple semiconductor dies are stacked upon one another, such as package-on-package (PoP) and system-in-package (SiP) packaging techniques. Some 3DICs are prepared by placing dies over dies on a semiconductor wafer level. 3DICs provide improved integration density and other advantages, such as faster speeds and higher bandwidth, because of the decreased length of interconnects between the stacked dies, as examples. However, there are many challenges related to 3DICs.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion. The figures may be simplified for the sake of clarity to better understand different aspects of the disclosure.

FIG. 1 is a cross-sectional view of an intermediate structure of a semiconductor package, in accordance with some embodiments.

FIG. 2 is a top view of the intermediate structure illustrated in FIG. 1, in accordance with some embodiments.

FIG. 3A and FIG. 3B are cross-sectional views illustrating a first substrate, in accordance with some embodiments.

FIG. 4A and FIG. 4B are cross-sectional views illustrating a second substrate, in accordance with some embodiments.

FIGS. 5A-5I are cross-sectional views illustrating various stages of forming a semiconductor package, in accordance with some embodiments.

FIGS. 6-8 are cross-sectional views illustrating package devices including the semiconductor package illustrated in FIG. 5I, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Typically, when performing photolithography processes (such as photoresist deposition, exposure, and development) on a wafer of a semiconductor package to transfer a pattern from a mask to a photoresist layer on the wafer, an alignment mark is used. For example, the alignment mark may be detected by an e-beam to ensure that the mask is aligned with the photoresist layer. Alignment accuracy is one of the key factors in photolithography processes. Alignment accuracy may be influenced by the material layers that the e-beam passes through, the alignment mark itself, and the like. For example, the intensity of the e-beam may decrease because of the existence of a substrate, such as a silicon substrate, over the alignment mark.

However, typically, the alignment mark is formed in the substrate of the same wafer on which photolithography processes are performed, and alignment accuracy may be affected by the thickness of the substrate covering the alignment mark. If the thickness of the substrate of the wafer is relatively thick, the intensity of the e-beam may decrease, causing alignment accuracy also decrease. As a result, the thickness of the substrate, the thickness of the wafer, and the overall thickness of the semiconductor package are all constrained.

Embodiments of semiconductor packages and methods for forming the same are provided. In this disclosure, when performing photolithography processes on one of the wafers of a semiconductor package, the alignment mark used in photolithography processes is formed in the peripheral portion of another wafer, which is not covered with any substrate. That is, the e-beam used in photolithography processes may detect the alignment mark without passing through any substrate. Therefore, high alignment accuracy can be achieved. In addition, the thickness of the substrate, the thickness of the wafer, and the overall thickness of the semiconductor package are no longer constrained. Therefore, more semiconductor components can be integrated into the wafers of the semiconductor package, thereby generating a higher bandwidth and consuming less power.

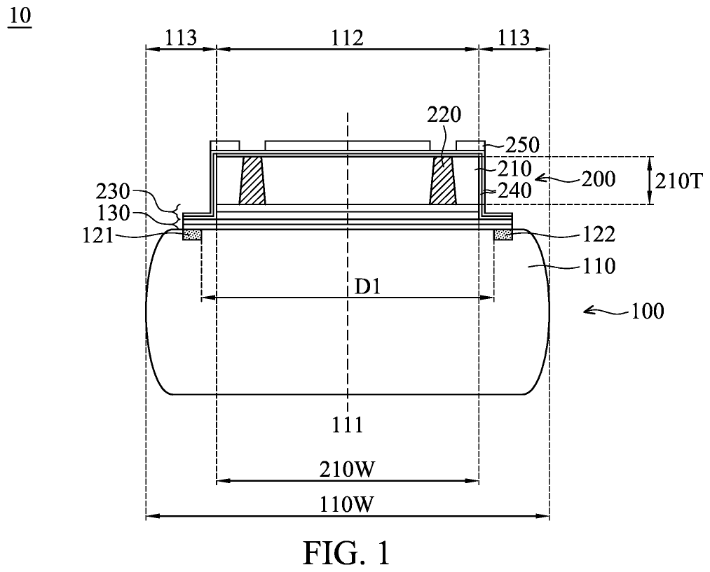

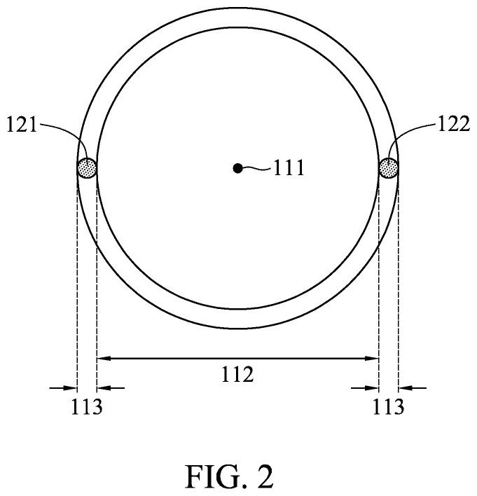

FIG. 1 is a cross-sectional view of an intermediate structure of a semiconductor package 10, in accordance with some embodiments. FIG. 2 is a top view of the intermediate structure illustrated in FIG. 1, in accordance with some embodiments. The intermediate structure of the semiconductor package 10 includes a first wafer 100 and a second wafer 200, as shown in FIG. 1 and FIG. 2 in accordance with some embodiments.

The first wafer 100 and the second wafer 200 may be a semiconductor wafer including glass, silicon, germanium, silicon oxide, aluminum oxide, silicon carbide, silicon germanium, diamond, a metal plate, a ceramic material, an organic material, and the like. Alternatively, the first wafer 100 and the second wafer 200 may include a compound semiconductor and/or an alloy semiconductor. The first wafer 100 and the second wafer 200 may include various layers, including conductive or insulating layers. The first wafer 100 and the second wafer 200 may include various doping configurations depending on design requirements.

The first wafer 100 and the second wafer 200 may include a die such as a logic die, a memory die, a passive device die, an analog die, a microelectromechanical system (MEMS) die, a radio frequency (RF) die, and a combination thereof. For example, a logic die may be a central processing unit die, a system on a chip (SoC) die, a system on integrated circuit (SOIC) die, a microcontroller die, and the like. A memory die may be a dynamic random access memory (DRAM) die, a static random access memory (SRAM) die, a high bandwidth memory (HBM) die, a NAND die, and the like.

The first wafer 100 includes a first substrate 110, a first alignment mark 121, a second alignment mark 122, and a first bonding structure 130. The first alignment mark 121 and the second alignment mark 122 are formed in the first substrate 110. The first bonding structure 130 is formed over the first substrate 110, the first alignment mark 121, and the second alignment mark 122.

The first substrate 110 has a central axis 111, a central portion 112, and a peripheral portion 113. The peripheral portion 113 surrounds the central portion 112. The first alignment mark 121 and the second alignment mark 122 are formed in the peripheral portion 113. In some embodiments, the first alignment mark 121 and the second alignment mark 122 are symmetrically formed relative to the central axis 111 of the first substrate 110.

The second wafer 200 includes a second substrate 210, a Through-Silicon Via (TSV) 220, a second bonding structure 230, a passivation structure 240, and a patterned photoresist layer 250. The second substrate 210 is located between the second bonding structure 230 and the passivation structure 240. In some embodiments, the second substrate 210 is substantially made of a silicon material. The TSV 220 penetrates through the second substrate 210 for providing electrical connection. The second bonding structure 230 is in contact with the first bonding structure 130. The passivation structure 240 is formed over the second substrate 210 and the TSV 220. The patterned photoresist layer 250 is formed over the passivation structure 240.

The first substrate 110 has a first width 110 W. The second substrate 210 has a second width 210 W. The first width 110 W of the first substrate 110 is greater than the second width 210 W of the second substrate 210. In fact, part of the second substrate 210 is trimmed off to make the first alignment mark 121 and the second alignment mark 122 not covered with the second substrate 210. In some embodiments, the distance D1 between the first alignment mark 121 and the second alignment mark 122 is greater than the second width 210 W of the second substrate 210. In some embodiments, the first alignment mark 121 and the second alignment mark 122 overlap the first bonding structure 130 and the passivation structure 240 vertically, but the first alignment mark 121 and the second alignment mark 122 do not overlap the second substrate 210 and the second bonding structure 230 vertically.

It should be noted that, in this disclosure, when performing photolithography processes on the second wafer 200, the first alignment mark 121 and the second alignment mark 122 may be used. For example, when a suitable combination of photolithography processes is used to pattern a photoresist layer to form the patterned photoresist layer 250 of the second wafer 200, the first alignment mark 121 and the second alignment mark 122 are used to ensure that the pattern is formed in the desired positions. That is, the alignment mark that is used (i.e. the first alignment mark 121 and/or the second alignment mark 122) is not formed in the second substrate 210, but formed in the peripheral portion of a different substrate (i.e. the peripheral portion 113 of the first substrate 110), which is not covered by any substrate. Therefore, high alignment accuracy can be achieved, and the thickness 210T of the second substrate 210 is not constrained. In some embodiments, the thickness 210T of the second substrate 210 is in a range from about 3 μm to about 60 μm. In some embodiments, the thickness 210T of the second substrate 210 is greater than 20 μm.

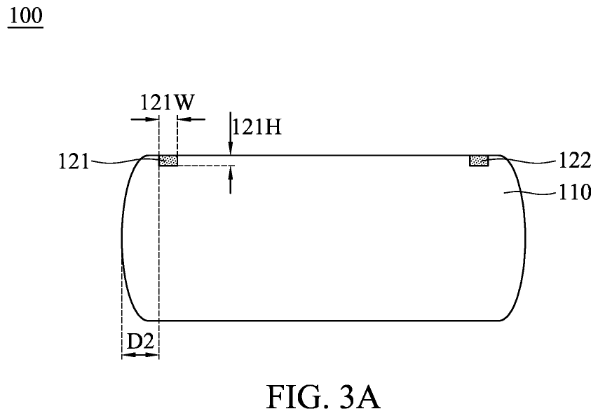

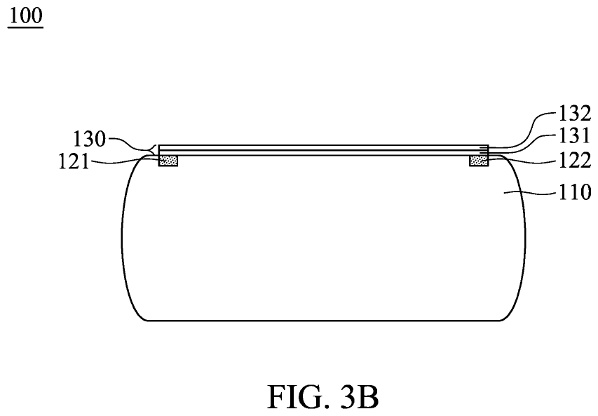

Next, please refer to FIG. 3A and FIG. 3B. FIG. 3A and FIG. 3B are cross-sectional views illustrating the first substrate 110, in accordance with some embodiments. Additional features may be added to the first substrate 110, and some of the features described below can be replaced, modified, or eliminated in other embodiments of the first substrate 110.

The first alignment mark 121 and the second alignment mark 122 are formed in the first substrate 110, as shown in FIG. 3A in accordance with some embodiments. For example, a sacrificial layer may be deposited over the first substrate 110, and the sacrificial layer may be patterned to form at least two openings in the peripheral portion 113 of the first substrate 110. The at least two openings may be filled with an alignment mark material to form the first alignment mark 121 and the second alignment mark 122.

In some embodiments, the alignment mark material includes a conductive material, such as copper, tungsten, gold, silver, aluminum, lead, tin, tantalum, and the like. Therefore, the first alignment mark 121 and the second alignment mark 122 may be electrically coupled to subsequently conductive elements, such as metal lines, traces, or electrical connectors. In some embodiments, the alignment mark material includes an insulating material, such as polybenzoxazole (PBO), polyimide (PI), an epoxy, and the like. Therefore, the first alignment mark 121 and the second alignment mark 122 are electrically isolated from subsequently conductive elements, such as metal lines, traces, or electrical connectors. In some embodiments, the alignment mark material includes a material that is different from the first substrate 110. In some embodiments, the alignment mark is formed by substrate etching, such as silicon (Si), silicon carbide (SiC), silicon oxide (SiO₂).

In some embodiments, the first alignment mark 121 and the second alignment mark 122 are substantially the same. The description related to the first alignment mark 121 may also be applied to the second alignment mark 122. It should be noted that, although two alignment marks are illustrated in the drawings, there may be more alignment marks.

In some embodiments, the height 121H of the first alignment mark 121 is in a range from about 50 nm to about 5000 nm. In some embodiments, the width 121 W of the first alignment mark 121 is in a range from about 0.5 μm to about 10 μm. If the height 121H of the first alignment mark 121 is greater than 5000 nm and/or the width 121 W of the first alignment mark 121 is greater than 10 μm, the usage of the alignment mark material may increase costs. If the height 121H of the first alignment mark 121 is less than 50 nm and/or the width 121 W of the first alignment mark 121 is less than 0.5 μm, alignment accuracy may not be satisfying because it may be difficult to detect the first alignment mark 121.

In some embodiments, the distance D2 between the edge of the first substrate 110 and the edge of the first alignment mark 121 is in a range from about 0.5 mm to about 4 mm, such as about 1 mm to about 3 mm, but is not limited thereto. As described above, the second substrate 210 is be trimmed off to make the first alignment mark 121 and the second alignment mark 122 not covered with the second substrate 210. If the distance D1 between the edge of the first substrate 110 and the edge of the first alignment mark 121 is greater than 4 mm, the second substrate 210 should be trimmed off more, causing a yield loss. If the distance D1 between the edge of the first substrate 110 and the edge of the first alignment mark 121 is less than 0.5 mm, it may be difficult to form the first alignment mark 121.

Then, the first bonding structure 130 is formed over the first substrate 110, the first alignment mark 121, and the second alignment mark 122, as shown in FIG. 3B in accordance with some embodiments. In some embodiments, the first bonding structure 130 includes more than one layer. For example, the first bonding structure 130 may be a double-layer structure including a first layer 131 and a second layer 132. In some embodiments, the first layer 131 and the second layer 132 may include silicon oxide or a silicon oxide containing material where silicon exists in various suitable forms. In some embodiments, the first layer 131 and the second layer 132 may include different materials. In some embodiments, the first layer 131 and the second layer 132 may be deposited by chemical vapor deposition (CVD), physical vapor deposition (PVD), atomic layer deposition (ALD), plasma enhanced CVD (PECVD), high-density plasma CVD (HDP-CVD), sub-atmospheric CVD (SACVD), and a combination thereof.

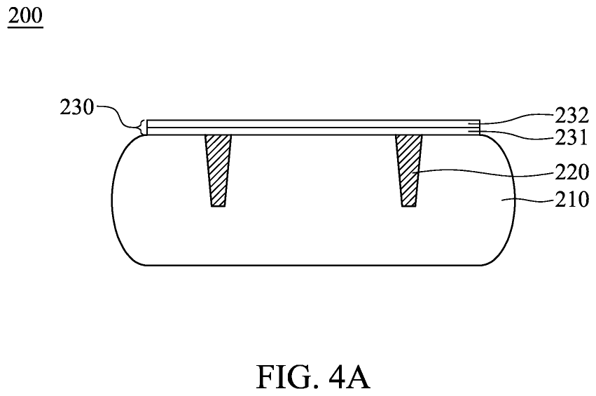

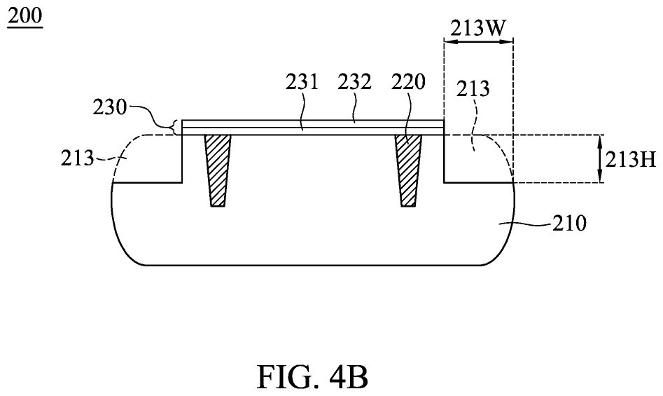

FIG. 4A and FIG. 4B are cross-sectional views illustrating the second substrate 120, in accordance with some embodiments. Additional features may be added to the second substrate 120, and some of the features described below can be replaced, modified, or eliminated in other embodiments of the second substrate 120.

The second bonding structure 230 is formed over the second substrate 210 and the TSV 220, as shown in FIG. 4A in accordance with some embodiments. In some embodiments, the second bonding structure 230 includes more than one layer. For example, the second bonding structure 230 may be a double-layer structure including a first layer 231 and a second layer 232. In some embodiments, the first layer 231 and the second layer 232 may include silicon oxide or a silicon oxide containing material where silicon exists in various suitable forms. In some embodiments, the first layer 231 and the second layer 232 may include different materials. In some embodiments, the first layer 231 and the second layer 232 may be deposited by CVD, PVD, ALD, PECVD, HDP-CVD, SACVD, and a combination thereof. In some embodiments, the width of the second bonding structure 230 is different from the width of the first bonding structure 130. In some embodiments, the width of the second bonding structure 230 is less than the width of the first bonding structure 130.

Part of the second bonding structure 230 and an edge portion 213 of the second substrate 210 are trimmed off, as shown in FIG. 4B in accordance with some embodiments. In some embodiments, the height 213H of the edge portion 213 is in a range from about 50 μm to about 500 μm. In some embodiments, the width 213 W of the edge portion 213 is in a range from about 0.5 mm to about 20 mm. By trimming off the edge portion 213, when attaching the second wafer 200 to the first wafer 100, the possibility of fracture and breakage in the first wafer 100 and the second wafer 200 may be reduced. In addition, by trimming off the edge portion 213, after the second wafer 200 is attached to the first wafer 100, the first alignment mark 121 and the second alignment mark 122 are not covered with the second substrate 210. The height 213H of the edge portion 213 and the width 213 W of the edge portion 213 may be adjusted based on the position of the first alignment mark 121 and the second alignment mark 122.

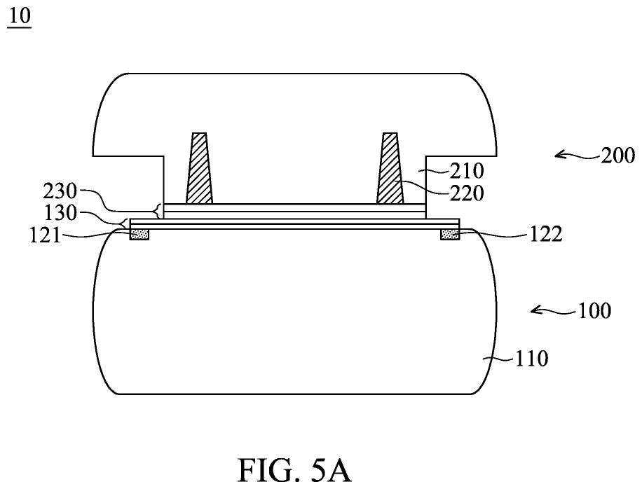

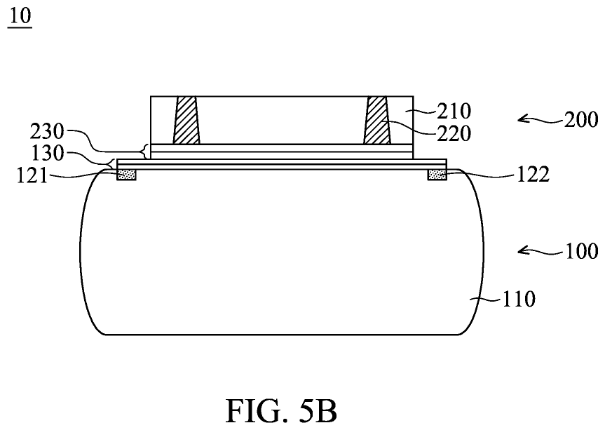

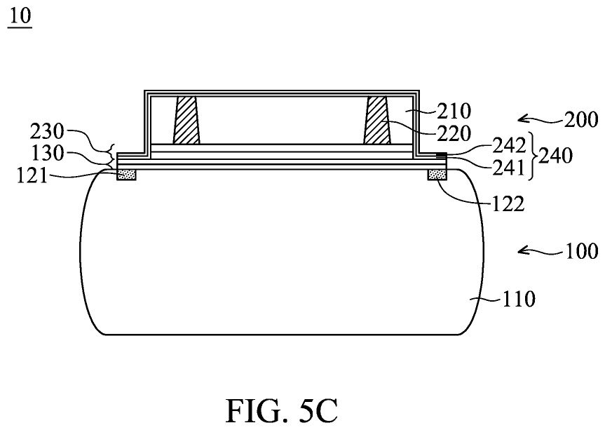

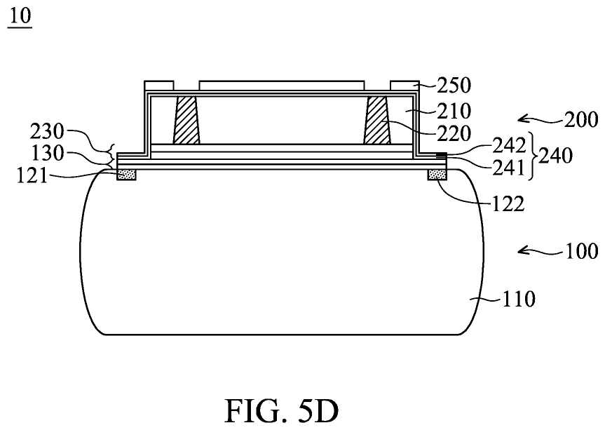

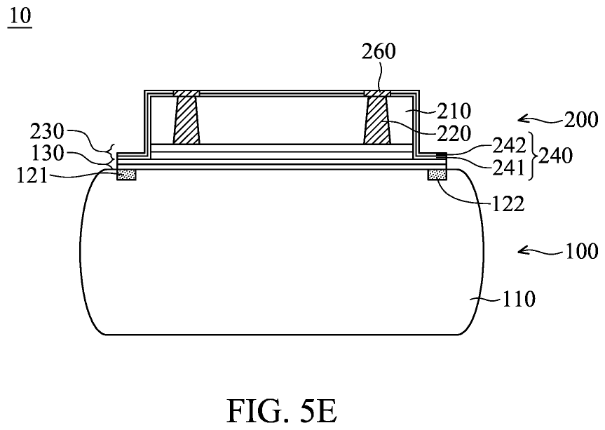

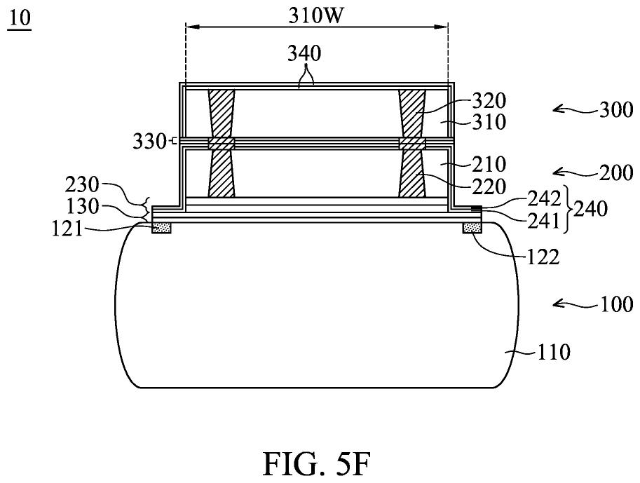

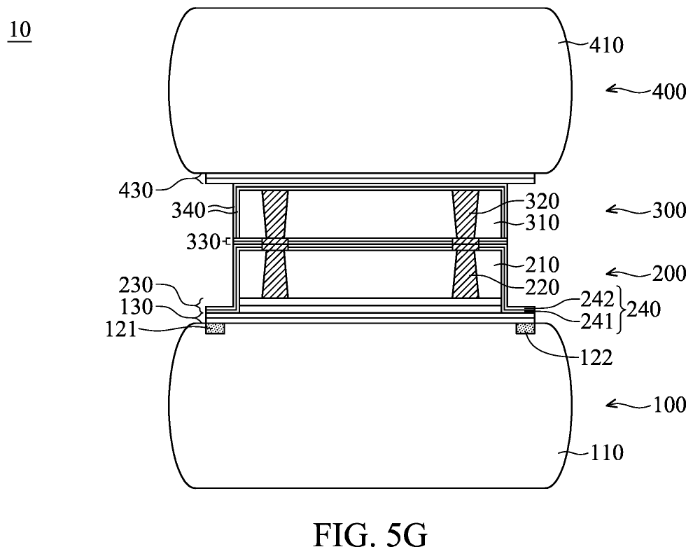

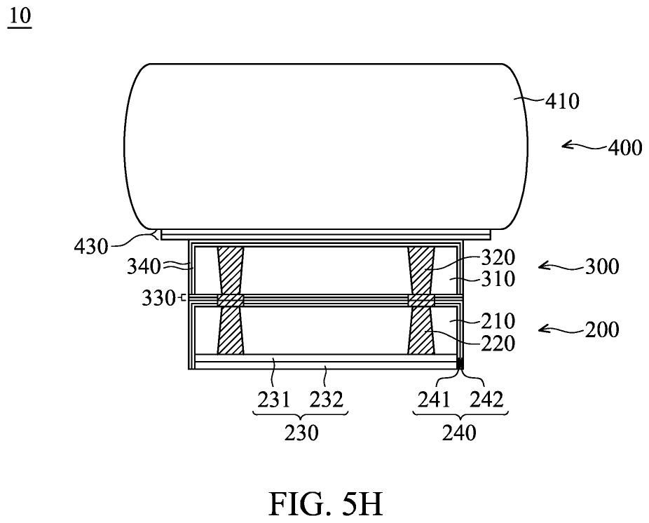

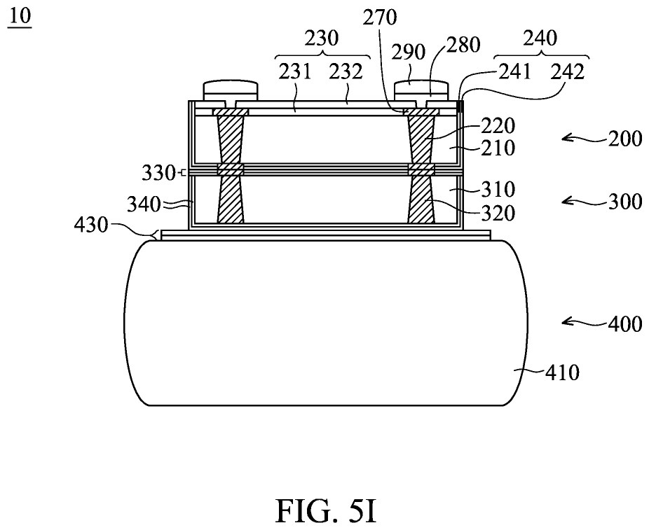

FIGS. 5A-5I are cross-sectional views illustrating various stages of forming the semiconductor package 10, in accordance with some embodiments. Additional features may be added to the semiconductor package 10, and some of the features described below can be replaced, modified, or eliminated in other embodiments of the semiconductor package 10.

The second wafer 200 is attached to the first wafer 100 via the first bonding structure 130 and the second bonding structure 230, as shown in FIG. 5A in accordance with some embodiments. In detail, in a top view, the second wafer 200 is located within the central portion 112 (denoted in FIG. 1 and FIG. 2) of the first substrate 110.

A thinning process is performed on the second wafer 200 until the TSV 220 in the second substrate 210 is exposed, as shown in FIG. 5B in accordance with some embodiments. The thinning process may be any suitable process, such as chemical mechanical planarization (CMP), mechanical grinding, wet etching, dry etching, or a combination thereof.

The passivation structure 240 is formed over the second substrate 210 and the TSV 220, as shown in FIG. 5C in accordance with some embodiments. In some embodiments, the passivation structure 240 includes a first passivation layer 241 and a second passivation layer 242. The first passivation layer 241 may include silicon oxide or a silicon oxide containing material where silicon exists in various suitable forms. In some embodiments, the second passivation layer 242 may include silicon nitride or a silicon nitride containing material where silicon exists in various suitable forms. In some embodiments, the first passivation layer 241 and the second passivation layer 242 may include different materials. In some embodiments, the first passivation layer 241 and the second passivation layer 242 may be deposited by CVD, PVD, ALD, PECVD, HDP-CVD, SACVD, and a combination thereof.

Photolithography processes may be performed on the second wafer 200 using the first alignment mark 121 and the second alignment mark 122, as shown in FIG. 5D in accordance with some embodiments.

The patterned photoresist layer 250 may be used to form a gap in the passivation structure 240, and the gap may be filled with a conductive material, such as copper, to form a first-side contact feature 260, as shown in FIG. 5E in accordance with some embodiments. The first-side contact feature 260 is electrically and physically connected to the TSV 220 to provide electrical connection.

A third wafer 300 including a third substrate 310 may be attached to the second wafer 200, as shown in FIG. 5F in accordance with some embodiments. It should be noted that, in some embodiments, the semiconductor package 10 does not include the third wafer 300. In some embodiments, the semiconductor package 10 includes more than three wafers. That is, the number of wafers included in the semiconductor package 10 may vary.

In some embodiments, before the third wafer 300 is attached to the second wafer 200, a third bonding structure 330 may be formed over the third wafer 300. The third bonding structure 330 may include conductive features and non-conductive features, and the conductive features may correspond to the first-side contact feature 260 of the second wafer 200.

In some embodiments, before the third wafer 300 is attached to the second wafer 200, the third wafer 300 may be trimmed, so that the first width 110 W of the first substrate 110 is greater than a third width 310 W of the third substrate 310 to make sure the first alignment mark 121 and the second alignment mark 122 does not overlap the third substrate 310 vertically. In some embodiments, the third width 310 W of the third substrate 310 is substantially the same as the second width 210 W of the second substrate 210. In some embodiments, the third width 310 W of the third substrate 310 is less than the second width 210 W of the second substrate 210.

In some embodiments, the third wafer 300 further includes a TSV 320 and a passivation structure 340. After the third wafer 300 is attached to the second wafer 200 via the first-side contact feature 260 and the third bonding structure 330, a thinning process may be performed on the third substrate 200 until the TSV 320 in the third wafer 300 is exposed. The thinning process may be any suitable process, such as CMP, mechanical grinding, wet etching, dry etching, or a combination thereof. In addition, a passivation structure may be formed over the third substrate 310 and photolithography processes may also be performed on the passivation structure of the third wafer 300 using the first alignment mark 121 and the second alignment mark 122.

In other words, semiconductor package 10 may include more than two wafers, and the first alignment mark 121 and the second alignment mark 122 may be used in photolithography processes performed on any wafers of the semiconductor package 10. Different photolithography processes performed on different wafers may involve using the same alignment marks formed in the first wafer 100 (i.e. the first alignment mark 121 and the second alignment mark 122). Therefore, there is no need to form alignment marks for each wafer of the semiconductor package 10, so the manufacturing processes may be simplified and costs may be reduced.

A fourth wafer 400 may be attached to the third wafer 300, as shown in FIG. 5G in accordance with some embodiments. Before the fourth wafer 400 is attached to the wafer 300, a fourth bonding structure 430 may be formed over a fourth substrate 410 of the fourth wafer 400. The fourth wafer 400 may be the last wafer that is integrated into the semiconductor package 10, so the width of the fourth wafer 400 is not constrained.

The first wafer 100 is removed to expose the second bonding structure 230 of the second wafer 200, as shown in FIG. 5H in accordance with some embodiments. The first wafer 100 may be polished (such as using a CMP process) until the second bonding structure 230 of the second wafer 200 is exposed.

The semiconductor package 10 is then flipped over, a second-side contact feature 270 is formed in second bonding structure 230, an under bump metallization (UBM) feature 280 is formed over the second-side contact feature 270, and a bump feature 290 is formed over the UBM feature 280, as shown in FIG. 5I in accordance with some embodiments. The second-side contact feature 270 and the first-side contact feature 260 are located on opposite sides of the second substrate 210. The UBM feature 280 is electrically and physically connected to the second-side contact feature 270. The bump feature 290 is electrically and physically connected to the UBM feature 280. Other semiconductor devices may be bonded to the chip package 10 via the UBM feature 280 and the bump feature 290.

In some embodiments, the UBM feature 280 may be made of a conductive material, such as copper, tungsten, gold, silver, aluminum, lead, tin, tantalum, and the like. In addition, the UBM feature 280 may contain an adhesion layer and/or a wetting layer. In some embodiments, the UBM feature 280 further includes a copper seed layer. In some embodiments, the UBM feature 280 includes an adhesion layer made of Ti/Cu and a wetting layer made of Cu. In some embodiments, the UBM feature 280 is formed by a plating process, such as an electrochemical plating process or an electroless process. In some embodiments, the bump feature 290 may be made of a conductive material, such as copper, tungsten, gold, silver, aluminum, lead, tin, tantalum, and the like.

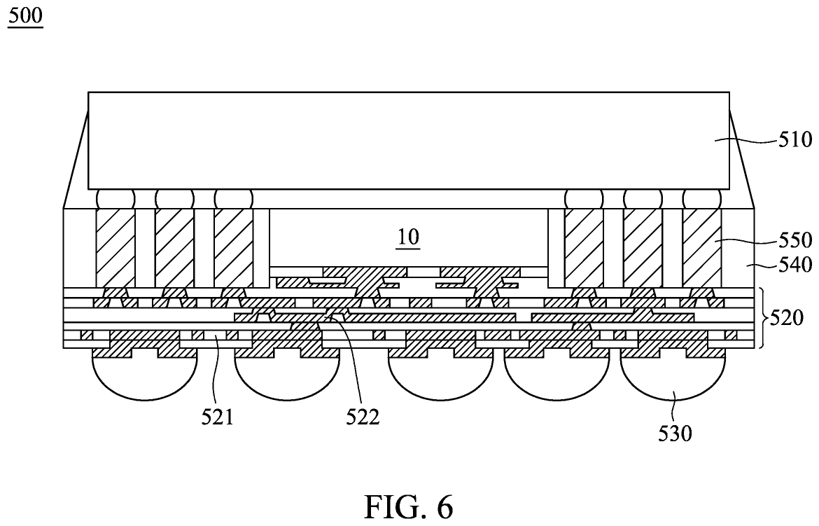

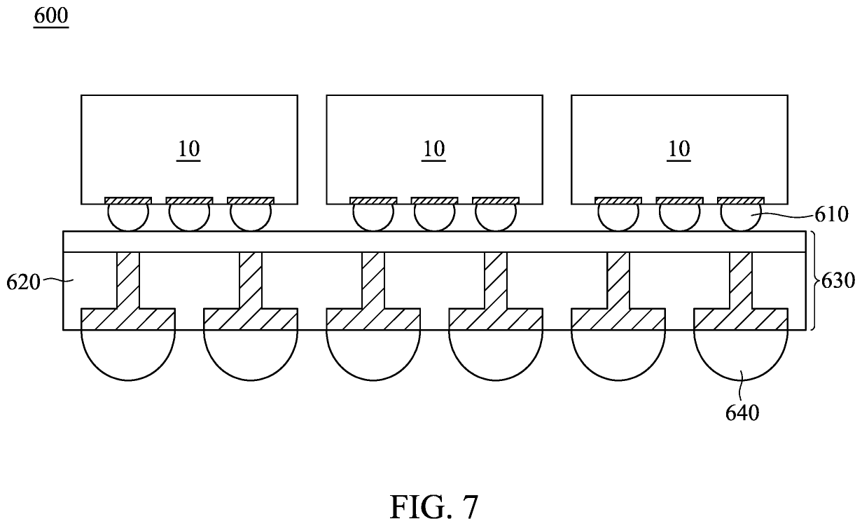

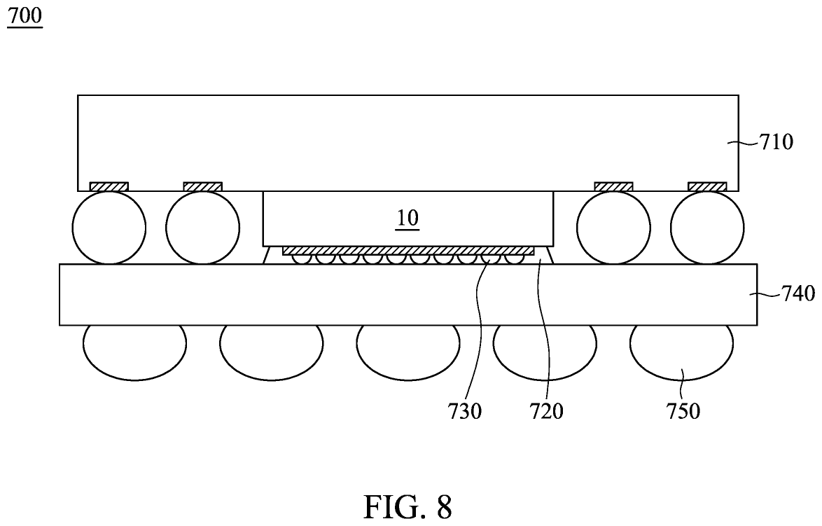

FIGS. 6-8 are cross-sectionals view illustrating package devices 500, 600, and 700 including the semiconductor package 10 illustrated in FIG. 5I, in accordance with some embodiments. Additional features may be added to the package devices 500, 600, and 700, and some of the features described below can be replaced, modified, or eliminated in other embodiments of the package devices 500, 600, and 700. The semiconductor package 10 is simplified in FIGS. 6-8 for the sake of clarity.

In addition to the semiconductor package 10, the package device 500 includes a semiconductor die 510, a fan-out redistribution structure 520, a plurality of conductive connectors 530, an underfill layer 540, and a plurality through integrated fan-out (InFO) vias (TIV) 550. The term “fan-out” means that the I/O pads on the semiconductor package 10 can be redistributed to a greater area than the semiconductor package 10 itself, and thus the number of I/O pads packed on the surfaces of the semiconductor package 10 can be increased.

The semiconductor die 510 may be a logic die, a memory die, a passive device die, an analog die, a MEMS die, a radio frequency RF die, and a combination thereof. For example, a logic die may be a central processing unit die, a SoC die, a SOIC die, a microcontroller die, and the like. A memory die may be a DRAM die, a SRAM die, a HBM die, a NAND die, and the like.

The fan-out redistribution layer 520 may include a plurality of dielectric layers 521 and a plurality of conductive layers 522. The conductive connectors 530 are formed over the conductive layers 522 that are exposed from the dielectric layers 521. In some embodiments, the conductive connectors 530 are controlled collapse chip connection (C4) bumps, solder bumps, copper bumps, micro bumps, electroless nickel-electroless palladium-immersion gold technique (ENEPIG) formed bumps, ball grid array (BGA) bumps, copper pillars, and the like. The underfill layer 540 is formed to surround the semiconductor package 10. In some embodiments, the underfill layer 540 is made of or includes a polymer material. The underfill layer 540 may include an epoxy-based resin. In some embodiments, the underfill layer 540 includes fillers dispersed in the epoxy-based resin. In some embodiments, the formation of the underfill layer 540 involves an injecting process, a spin-on process, a dispensing process, a film lamination process, an application process, one or more other applicable processes, or a combination thereof. In some embodiments, a thermal curing process is used during the formation of the underfill layer 540. The TIVs 550 penetrate the underfill layer 540 to provide electrical connection.

In addition to the semiconductor package 10, the package device 600 includes a plurality of contact pads 610, an interposer 620, a redistribution structure 630, and a plurality of conductive connectors 640.

The contact pads 610 are formed under the semiconductor package 10 to provide electrical connection. The interposer 620 may be fabricated from a silicon material, an organic (laminate) material, a polymer-based material, and the like. The interposer 620 may be attached to a carrier such as a printed circuit board (PCB). The redistribution structure 630 may include metal lines and vias to provide electrical connection to route power, ground, and signals from the top surface of the interposer 620 to the bottom surface of the interposer 620. In some embodiments, the conductive connectors 640 are C4 bumps, solder bumps, copper bumps, micro bumps, ENEPIG formed bumps, BGA bumps, copper pillars, and the like.

In addition to the semiconductor package 10, the package device 700 includes a semiconductor die 710, an underfill layer 720, a plurality of contact pads 730, a bottom substrate 740, and a plurality of conductive connectors 750.

The semiconductor die 710 may be a logic die, a memory die, a passive device die, an analog die, a MEMS die, a radio frequency RF die, and a combination thereof. For example, a logic die may be a central processing unit die, a SoC die, a SOIC die, a microcontroller die, and the like. A memory die may be a DRAM die, a SRAM die, a HBM die, a NAND die, and the like. The contact pads 730 are formed within the underfill layer 720 to provide electrical connection. In some embodiments, the conductive connectors 750 are C4 bumps, solder bumps, copper bumps, micro bumps, ENEPIG formed bumps, BGA bumps, copper pillars, and the like. In some embodiments, the semiconductor package 10 may be connected to the bottom substrate 740 by flip-chip bonding technology.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

As described above, for a semiconductor package, when performing photolithography processes on one of the wafers of the semiconductor package, the alignment mark used in photolithography processes is formed in the peripheral portion of another wafer, which is not covered with any substrate. Therefore, high alignment accuracy can be achieved. In addition, the thickness of the substrate, the thickness of the wafer, and the overall thickness of the semiconductor package are no longer constrained. Therefore, more semiconductor components can be integrated into the wafers of the semiconductor package, thereby generating a higher bandwidth and consuming less power. Furthermore, the semiconductor package may include more than two wafers, and photolithography processes performed on any wafers may involve using the same alignment marks. Therefore, there is no need to form alignment marks for each wafer of the semiconductor package, so the manufacturing processes may be simplified and costs may be reduced.

In accordance with some embodiments, a method for forming a semiconductor package is provided. The method includes forming a first alignment mark in a first substrate of a first wafer and forming a first bonding structure over the first substrate. The method also includes forming a second bonding structure over a second substrate of a second wafer and trimming the second substrate, so that a first width of the first substrate is greater than a second width of the second substrate. The method further includes attaching the second wafer to the first wafer via the first bonding structure and the second bonding structure, thinning the second wafer until a through-substrate via in the second substrate is exposed, and performing a photolithography process on the second wafer using the first alignment mark.

In accordance with some embodiments, a method for forming a semiconductor package is provided. The method includes forming an alignment mark in a peripheral portion of a first substrate of a first wafer and bonding a second wafer to a central portion of the first substrate. The central portion is surrounded by the peripheral portion. The method also includes depositing a passivation structure over a second substrate of the second wafer and performing a photolithography process on the second wafer to form a gap in the passivation structure using the alignment mark. The method further includes filling a conductive material in the gap to form a first-side contact feature. The first-side contact feature is in contact with a through-substrate via in the second substrate.

In accordance with some embodiments, a method for forming a semiconductor package is provided. The method includes depositing a sacrificial layer over a first substrate of a first wafer and patterning the sacrificial layer to form at least two openings in a peripheral portion of the first substrate. The peripheral portion surrounds a central portion of the first substrate. The method also includes filling the at least two openings with an alignment mark material to form at least two alignment marks. The method also includes attaching a second wafer to the central portion of the first substrate and performing a photolithography process on the second wafer using the at least two alignment marks.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor package, comprising:
forming a first alignment mark in a first substrate of a first wafer;
forming a first bonding structure over the first substrate;
forming a second bonding structure over a second substrate of a second wafer;
trimming the second substrate, so that a first width of the first substrate is greater than a second width of the second substrate;
attaching the second wafer to the first wafer via the first bonding structure and the second bonding structure;
thinning the second wafer until a through-substrate via in the second substrate is exposed; and
performing a photolithography process on the second wafer using the first alignment mark.

2. The method as claimed in claim 1, wherein the first substrate comprises a central portion and a peripheral portion surrounding the central portion, the second substrate is attached to the central portion of the first substrate, and the first alignment mark is formed in the peripheral portion of the first substrate.

3. The method as claimed in claim 1, wherein a height of the first alignment mark is in a range from about 50 nm to about 5000 nm.

4. The method as claimed in claim 1, wherein a width of the first alignment mark is in a range from about 0.5 μm to about 10 μm.

5. The method as claimed in claim 1, wherein a distance between an edge of the first substrate and an edge of the first alignment mark is in a range from about 0.5 mm to about 4 mm.

6. The method as claimed in claim 1, wherein a thickness of the second substrate is in a range from about 3 μm to about 60 μm.

7. The method as claimed in claim 1, wherein the second substrate overlaps the central portion of the first substrate vertically without overlapping the first alignment mark vertically.

8. The method as claimed in claim 1, further comprising forming a second alignment mark in peripheral portion of the first substrate, and the first alignment mark and the second alignment mark are symmetrically formed relative to a central axis of the first substrate.

9. The method as claimed in claim 8, wherein a distance between the first alignment mark and the second alignment mark is greater than the second width of the second substrate.

10. The method as claimed in claim 1, further comprising forming a first-side contact feature over the second substrate and attaching a third wafer to the second wafer via the first-side contact feature.

11. The method as claimed in claim 10, further comprising:
removing the first wafer to expose the second bonding structure of the second wafer;
forming a second-side contact feature in the second bonding structure, wherein the second-side contact feature and the first-side contact feature are located on opposite sides of the second substrate;
forming an under bump metallization feature over the second-side contact feature; and
forming a bump feature over the under bump metallization feature.

12. The method as claimed in claim 1, further comprising:
forming a third bonding structure over a third substrate of a third wafer;
trimming the third substrate, so that the first width of the first substrate is greater than a third width of the third substrate;
attaching the third wafer to the second wafer via the third bonding structure;
thinning the third substrate until a through-substrate via in the third substrate is exposed; and
performing a photolithography process on the third wafer using the first alignment mark.

13. A method for forming a semiconductor package, comprising:
forming an alignment mark in a peripheral portion of a first substrate of a first wafer;
bonding a second wafer to a central portion of the first substrate, wherein the central portion is surrounded by the peripheral portion;
depositing a passivation structure over a second substrate of the second wafer;
performing a photolithography process on the second wafer to form a gap in the passivation structure using the alignment mark; and
filling a conductive material in the gap to form a first-side contact feature;
wherein the first-side contact feature is in contact with a through-substrate via in the second substrate.

14. The method as claimed in claim 13, wherein trimming the second substrate comprises trimming an edge portion of the second substrate, a height of the edge portion is in a range from about 50 μm to about 500 μm, and a width of the edge portion is in a range from about 0.5 mm to about 20 mm.

15. The method as claimed in claim 13, wherein a distance between an edge of the first substrate and an edge of the alignment mark is in a range from about 0.5 mm to about 4 mm.

16. The method as claimed in claim 13, further comprising attaching a third wafer to the second wafer via the first-side contact feature.

17. A method for forming a semiconductor package, comprising:
depositing a sacrificial layer over a first substrate of a first wafer;
patterning the sacrificial layer to form at least two openings in a peripheral portion of the first substrate, wherein the peripheral portion surrounds a central portion of the first substrate;
filling the at least two openings with an alignment mark material to form at least two alignment marks;
attaching a second wafer to the central portion of the first substrate; and
performing a photolithography process on the second wafer using the at least two alignment marks.

18. The method as claimed in claim 17, wherein the first wafer further comprises a first bonding structure, the second wafer further comprises a second bonding structure in contact with the first bonding structure, and a width of the first bonding structure is different from a width of the second bonding structure.

19. The method as claimed in claim 18, wherein the at least two alignment marks overlap the first bonding structure vertically without overlapping the second bonding structure vertically.

20. The method as claimed in claim 17, wherein a thickness of the second substrate is greater than 20 μm.
